(19) United States
(12) Patent Application Publication
(10) Pub. No.: US 2009/0168389 A1
(43) Pub. Date: Jul. 2, 2009

(54) HIGH FREQUENCY COMMUNICATION APPARATUS AND WATERPROOF STRUCTURE THEREOF AND MANUFACTURING METHOD FOR WATERPROOF STRUCTURE

(75) Inventors: HSIANG HAO SUNG, Hsinchu (TW); TUNG YI KO, Hsinchu (TW)

Correspondence Address: WPAT, PC;INTELLECTUAL PROPERTY ATTORNEYS, 2030 MAIN STREET, SUITE 1300, IRVINE, CA, 92614, US

(73) Assignee: MICROELECTRONICS TECHNOLOGY INC., HSINCHU (TW)

(21) Appl. No.: 12/140,972

(22) Filed: Jun. 17, 2008

(30) Foreign Application Priority Data
Dec. 31, 2007 (TW) 096151367

(51) Int. Cl. H05K 5/06

(52) U.S. Cl. 361/814

(57) ABSTRACT

A waterproof structure of a high frequency communication apparatus accommodates a waveguide, the waveguide comprising a waveguide channel and an extending portion connected to the waveguide channel. The waterproof structure comprises a case body and a case cover. The case cover bonds with the case body to form an inner space accommodating the waveguide and an opening through which the extending portion penetrates outwards. The case body and the case cover are bonded by glue, and the extending portion and the case body and the case cover around the opening are bonded by glue, thereby preventing moisture incursion.

### BACKGROUND OF THE INVENTION

(A) Field of the Invention

The present invention is related to a high frequency communication apparatus, and, more specifically, to a waterproof high frequency communication apparatus and the waterproof structure thereof and manufacturing method for the waterproof structure.

(B) Description of Related Art

Generally, microwave signals transmitted between satellites and ground level do not easily penetrate walls, roofs or glass windows. Therefore, satellite transmitters are usually placed outdoors and antennas are directed toward satellites to obtain superior transmission efficiency.

FIG. 1 illustrates a cross-sectional view of a waterproof structure of a traditional outdoor high frequency communication apparatus including, e.g., a waveguide. The waterproof structure is used to protect the inner satellite transmitter (not shown) from exposure to the environment with, for example, rainwater or moisture that would damage the apparatus. The waterproof structure 10 includes an upper cover 11 and a base 12. To protect a satellite signal transmitter, the satellite signal transmitter is placed in an inner space 15 formed by the upper cover 11 and the base 12 of the waterproof structure 10. For outdoor use with waterproof capability, the waterproof structure 10 comprises an O-ring 13 placed between the upper cover 11 and the base 12. The O-ring 13 is pressed and deformed to achieve a waterproof seal. Moreover, screws 14 are employed to bond the upper cover 11 and the base 12.

However, the traditional waterproof structure 10 has several shortcomings. First, the upper cover 11 and the base 12 are usually formed by die casting. When the screws 14 and the O-ring 13 are used in combination, the gap between the coarse combination surfaces 111 and 121 does not effectively prevent high frequency signal (Ku band, C band or Ka band) leakages, and cannot isolate outside noise interferences. Second, when assembling or disassembling the upper cover 11 and the base 12, the screws have to be released or fastened, thereby requiring a long time for assembly and testing.

### SUMMARY OF THE INVENTION

The present invention provides a high frequency communication apparatus and the waterproof structure thereof and the manufacturing method for the waterproof structure. Glue such as epoxy resin or silicone are used for bonding the waterproof structure. Because glue is of superior plasticity, in addition to providing superior waterproof efficacy, the problems of sand voids and cracks of the mechanical mold can be solved, thereby providing a stable and robust waterproof mechanism for two bonding members.

In accordance with the present invention, a waterproof structure of a high frequency communication apparatus accommodates a waveguide, the waveguide comprising a waveguide channel and an extending portion connected to the waveguide channel. The waterproof structure comprises a case body and a case cover. The case cover bonds with the case body to form an inner space accommodating the waveguide and an opening through which the extending portion penetrates outwards. The case body and the case cover are bonded by glue, and the extending portion and the case body and the case cover around the opening are bonded by glue, thereby avoiding moisture incursion.

In an embodiment, the bonding of the waterproof structure includes two steps. First, the case body and the case cover are bonded by glue, and then the extending portion and the case cover and case body around the opening are bonded by glue.

### BRIEF DESCRIPTION OF THE DRAWINGS

FIG. 1 illustrates a cross-sectional view of a waterproof structure of a known high frequency communication apparatus;

FIGS. 2A and 2B exemplarily illustrate a waterproof structure of a high frequency communication apparatus in accordance with the present invention; and

FIGS. 3 and 4 exemplarily illustrate the bonding of the waterproof structure of a high frequency communication apparatus.

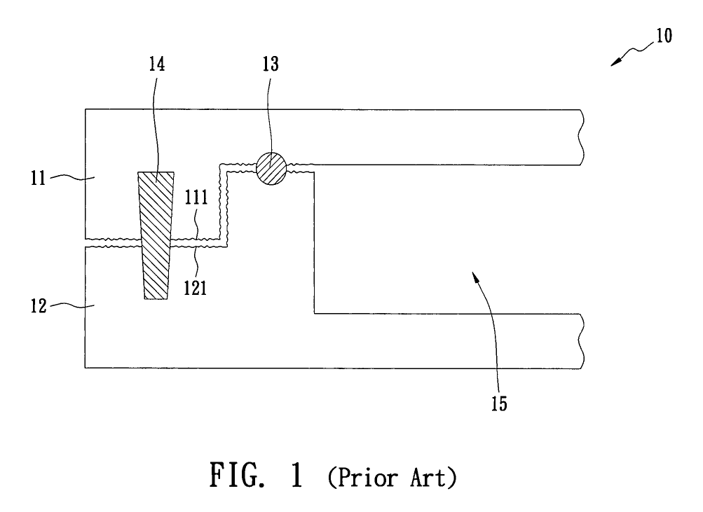

### DETAILED DESCRIPTION OF THE INVENTION

The high frequency communication apparatus and the waterproof structure thereof and manufacturing method for waterproof structure of the present invention are described with reference to the appended drawings as follows.

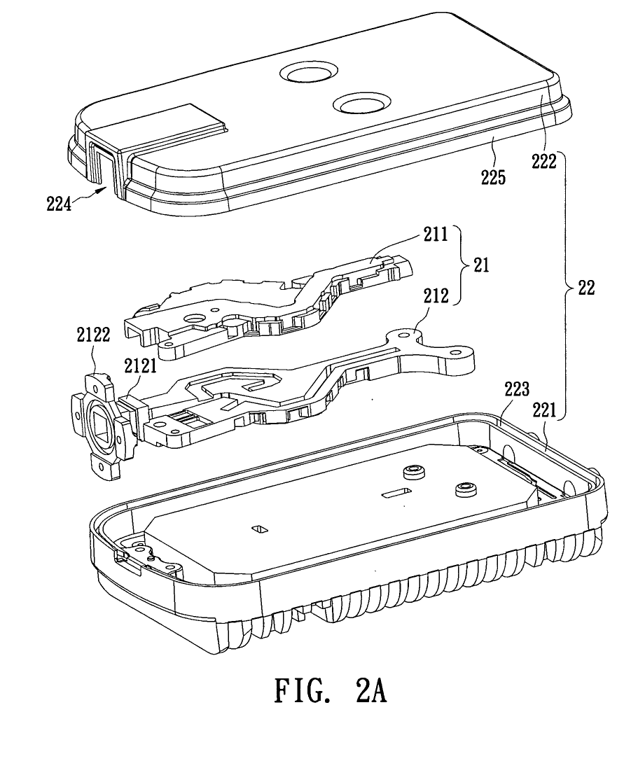

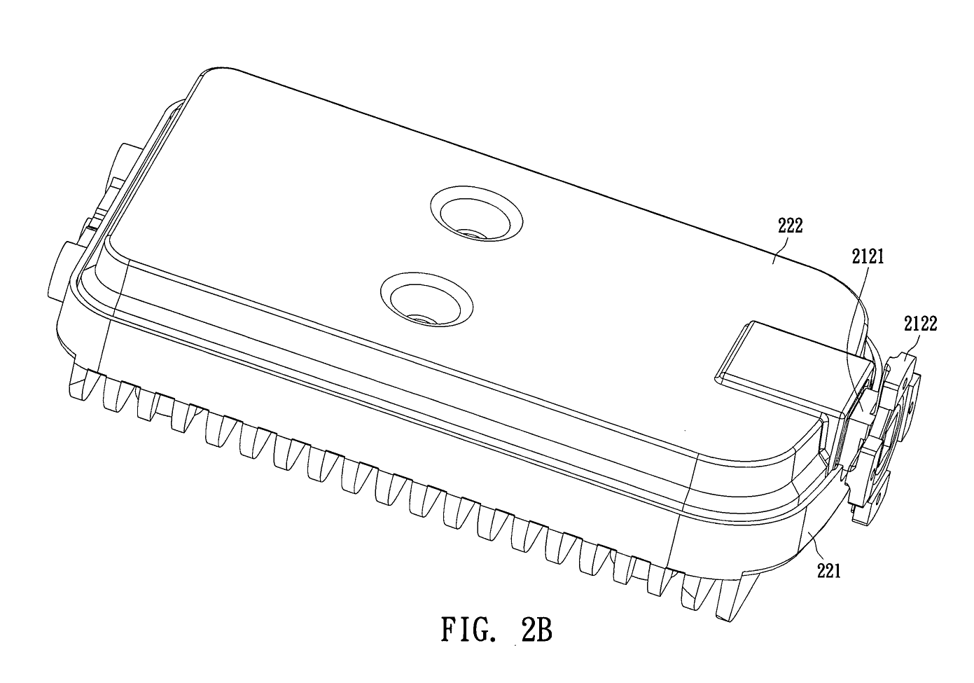

FIG. 2A is an exploded diagram of a waterproof structure of a high frequency communication apparatus in accordance with an embodiment of the present invention. In this embodiment, a waveguide 21 consists of a first discrete member 211 and a second discrete member 212. The first and second discrete members 211 and 212 include some parts of the waveguide 21. The second discrete member 212 with an extending channel therethrough includes an extending portion 2121 at the front end thereof. The extending channel has the same shape as the waveguide channel of the waveguide 21, and the cross-section of the extending channel in connection with the waveguide 21 has the same area as the cross-section of the waveguide channel. Therefore, the extending portion can be regarded as an extension of the waveguide. The extending portion 2121 is provided with a securing member 2122 that is used to secure the assembly of the receiver/transmitter to a satellite antenna structure. The securing member 2122 may be a flange. The second discrete member 212, the extending portion 2121 and the securing member 2122 are building-integrated and seamless therebetween.

The waterproof structure 22 comprises a case body 221 and a case cover 222. The upper rim of the case body 221 has a groove 223 with a shape complying with the bulge 225 at the lower rim of the case cover 222.

The groove 223 and/or the bulge 225 may be bonded by daubing glue thereon. Preferably, a dispensing machine may be used for evenly daubing glue. Accordingly, when the case cover 222 and the case body 221 are combined, the bulge 225 is embedded with and glued to the groove 223 to form the waterproof structure 22.

The assembled waterproof structure 22 forms an opening 224 through which the extending portion 2121 penetrates. The opening 224 with the extending portion 2121 therethrough has to be sealed. Likewise, the portion of the case body 221 and the case cover 222 around the opening 224 can be daubed with glue to form a waterproof barrier.

FIG. 2B is an illustration of the assembled waterproof structure. FIG. 2A shows the waterproof design, wherein all the seams have to be blocked to isolate the waveguide 21 from the atmosphere. The integral design can provide complete waterproof efficacy for the communication apparatus. The communication band of the communication apparatus is Ku band, C band or Ka band. The waveguide 21 is placed in the waterproof structure 22 constituted of the case body 221 and the case cover 222. In addition to the seam between the case body 221 and case cover 222, there is a seam between the extending portion 2121 and the opening 224 of the waterproof structure 22. All the seams are glued to isolate the interior of the waterproof structure 22 from the outside environment, so as to prevent moisture incursion. The airtight seal of the structure is in compliance with IP68 specification.

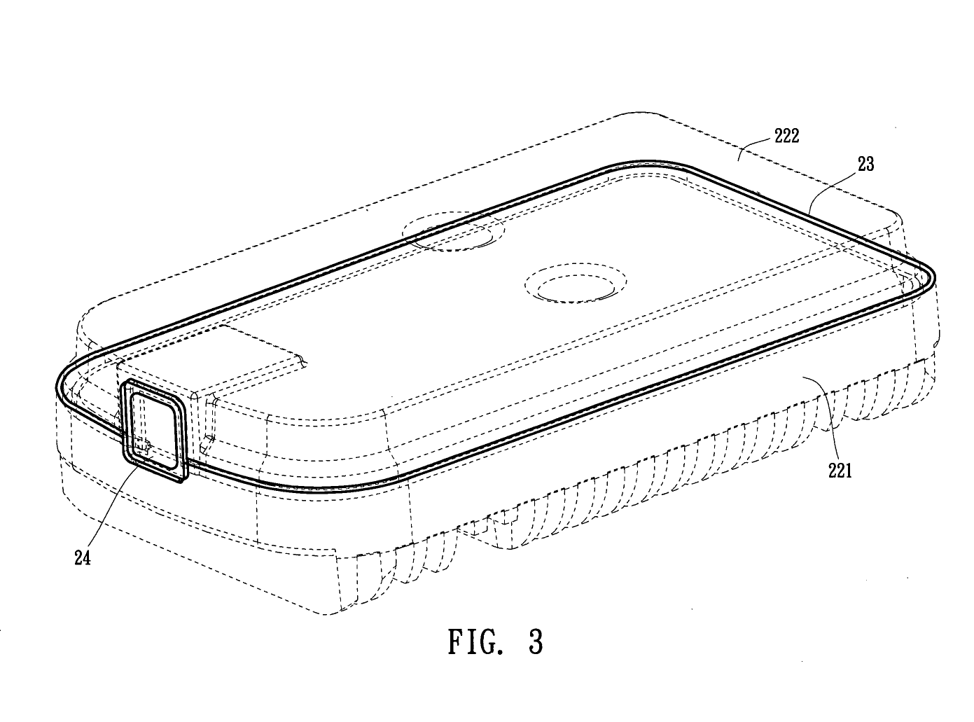

FIG. 3 is a three-dimensional diagram illustrating glue positions. In practice, glue 23 may be formed on the groove 223 and/or the bulge 225 by a dispenser first. After the case body 221 and the case cover 222 are joined, glue 24 is dispensed around the opening 224 for airtight bonding. In other words, the waterproof seal of the three-dimensional structure can be achieved by a two-step dispensing process. The glue 23 and 24 may be silicone or epoxy resin that is suitable for outdoor applications.

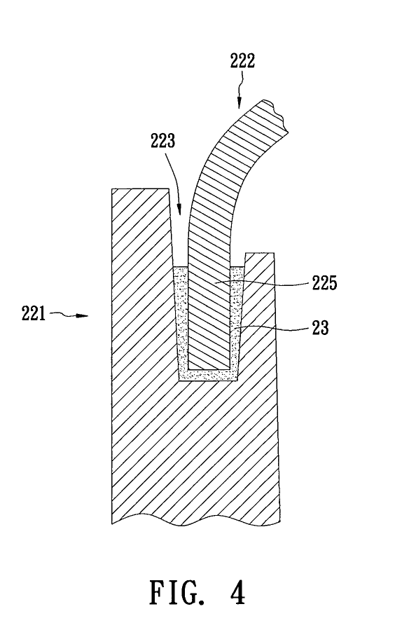

FIG. 4 illustrates the bonding of the case cover 222 and the case body 221. The bulge 225 of the case cover 222 is inserted into the groove 223 of the case body 221, and they may be bonded by glue 23.

Because glue such as silicone or epoxy resin has superior waterproof efficacy, problems generated by sand voids and cracks on mechanical mold can be solved, thereby providing a stable and robust waterproof mechanism for two bonding members.

According to the present invention, glue serving as waterproof material can bond the members of the same or different materials in comparison with welding or other bonding methods. Therefore, regardless of whether the case body 221 and the case cover 222 are made of aluminum alloys or plastics, or one is made of aluminum alloy and the other is made of plastics, glue can provide superior waterproof efficacy.

Moreover, bonding two members by glue further provides the following advantages: larger bonding tolerance is allowed; the members with coarse surfaces can be used; and weight can be reduced by, e.g., removing the material in the groove 223.

The above-described embodiments of the present invention are intended to be illustrative only. Numerous alternative embodiments may be devised by those skilled in the art without departing from the scope of the following claims.

What is claimed is:

1. A waterproof structure of a high frequency communication apparatus accommodating a waveguide, the waveguide comprising a waveguide channel and an extending portion connected to the waveguide channel, the waterproof structure comprising:
a case body; and
a case cover combining with the case body to form an inner space accommodating the waveguide and an opening through which the extending portion penetrates outwards;
wherein the case body and the case cover are bonded by glue, and the extending portion and the case body and the case cover around the opening are bonded by glue.

2. The waterproof structure of claim 1, wherein the waveguide further comprises a flange connected to an end of the extending portion.

3. The waterproof structure of claim 1, wherein the glue is epoxy resin or silicone.

4. The waterproof structure of claim 1, wherein the case body and case cover are made of the same or different materials.

5. The waterproof structure of claim 1, wherein the case body and the case cover are bonded by glue first, and the extending portion and the case body and the case cover around the opening are bonded by glue afterwards.

6. The waterproof structure of claim 1, wherein the case body comprises a groove and the case cover comprises a bulge, and the bulge is inserted into the groove and is bonded to the groove by the glue.

7. A high frequency communication apparatus, comprising:
a waveguide comprising a waveguide channel and an extending portion; and
a waterproof structure comprising a case body and a case cover, wherein the case body and the case body are bonded to form an inner space to accommodate the waveguide and an opening through which the extending portion penetrates outwards, the case body and the case cover are bonded by glue, and the extending portion and the case body and the case cover around the opening are bonded by glue.

8. The high frequency communication apparatus of claim 7, wherein the high frequency communication apparatus has a communication band of Ku band, C band or Ka band.

9. The high frequency communication apparatus of claim 7, further comprising a flange connected to an end of the extending portion.

10. The high frequency communication apparatus of claim 7, wherein the glue is epoxy resin or silicone.

11. The high frequency communication apparatus of claim 7, wherein the case body or case cover are made of same or different materials.

12. The high frequency communication apparatus of claim 7, wherein the case body and the case cover are bonded by glue first, and the extending portion and the case body and the case cover around the opening are bonded by glue afterwards.

13. A method for manufacturing a waterproof structure of a high frequency communication apparatus, the waveguide comprising a waveguide channel and an extending portion connected to the waveguide channel, the method comprising the steps of:
providing glue at positions at which the case body and the case cover are to be bonded;
bonding the case body and the case cover by glue to form an opening through which the extending portion penetrates outwards; and
bonding the extending portion and the case body and the case cover around the opening by glue.

14. The method for manufacturing a waterproof structure of claim 13, wherein the positions at which the case body and the case cover are to be bonded comprise a groove of the case body and a bulge of the case cover, and the groove corresponds to the bulge.

15. The method for manufacturing a waterproof structure of claim 13, wherein the glue is epoxy resin or silicone.
